(19) United States
(12) Patent Application Publication
(10) Pub. No.: US 2009/0243705 A1
(43) Pub. Date: Oct. 1, 2009

(54) High Voltage Tolerative Driver Circuit

(75) Inventors: Jiann-Tseng Huang, Hsinchu (TW); Sung-Chieh Lin, Hsin-Chu (TW)

Correspondence Address: K & L GATES LLP;IP Docketing, 630 Hansen Way, Palo Alto, CA, 94304, US

(73) Assignee: Taiwan Semiconductor Manufacturing Co., Ltd.

(21) Appl. No.: 12/057,585

(22) Filed: Mar. 28, 2008

(51) Int. Cl. G11C 5/14

(52) U.S. Cl. 327/530

(57) ABSTRACT

A high voltage tolerative inverter circuit is disclosed, which comprises a PMOS transistor with a source and drain being connected to a first high voltage power supply (VDDQ) and an output terminal, respectively, a gate of the PMOS transistor being controlled by a first signal having a voltage swing between the VDDQ and a low voltage power supply (VSS), and a NMOS transistor with a source and drain being connected to the VSS and the output terminal, a gate of the NMOS transistor being controlled by a second signal having a voltage swing between a second high voltage power supply (VDD) and the VSS, wherein the VDD is lower than the VDDQ, and the voltage swings between the VDDQ and the VSS by the first signal and between the VDD and the VSS by the second signal are always in the same direction.

### BACKGROUND

The present invention relates generally to integrated circuit (IC) designs, and more particularly to drive circuit designs.

Semiconductor field-effect transistors use silicon dioxide, or “oxide”, as a gate material. For a given thickness, oxide can only tolerate a certain amount of voltage stress. An oxide layer can break down instantaneously at 0.8-1.1 V per angstrom of thickness. Excessive voltage even far lower than the above break down voltage can degrade gate oxide integrity (GOI), and cause eventual failure.

In modern semiconductor integrated circuits (ICs) there are always situations where gate oxides may be subjected to excessive voltages. For instance, in Flash memory devices, program or erase may require a voltage as high as 18V. In electrical fuse circuits, programming may also require a voltage as high as 2.7V while the normal operating voltage is only 1.2V. These high voltages will particularly put stress on driver devices which deliver such high voltages. A complimentary metal-oxide-semiconductor (CMOS) inverters are most commonly used such driver device. FIG. 1 illustrates a conventional inverter 100 with a P-type metal-oxide-semiconductor (PMOS) transistor 110 connected to a high voltage power supply, VDDQ, and an N-type metal-oxide-semiconductor (NMOS) transistor 120 connected to a ground, VSS. Gates of both the PMOS transistor 110 and the NMOS transistor 120 are connected together to an input terminal, IN, of the inverter 100. Drains of both the PMOS transistor 110 and the NMOS transistor 120 are connected together to an output terminal, OUT, of the inverter 100. Substrates of the PMOS transistor 110 and the NMOS transistor 120 are connected the VDDQ and VSS, respectively. When the input terminal IN is supplied with the VDDQ, the gate oxide of the NMOS transistor 120 will be subjected to the VDDQ, while the gate oxide of the PMOS transistor 110 is not stressed. On the other hand, when the input terminal IN is supplied with the VSS, the gate oxide of the PMOS transistor 110 will be subjected to the VDDQ. Empirically, the gate oxide of the NMOS transistor 120 is much more susceptible to the voltage stress than the PMOS transistor 110. Table 1 records a set of time-dependent dielectric breakdown (TDDB) data on both NMOS and PMOS gate oxides. Under the same stress voltage, the gate oxide of the NMOS transistor is about 55 times weaker than that of the PMOS transistor.

TABLE 1
TDDB T0.1%

| | NMOS Gate [140 nm] | PMOS Gate [140 nm] |
|---|---|---|
| 2.75 V | 3.95 [ms] | 1.37 [s] |

As such, what is desired is an inverter that has improved NMOS gate oxide robustness and hence better overall high voltage tolerance.

### SUMMARY

In view of the foregoing, the present invention provides a high voltage tolerative inverter circuit which comprises a PMOS transistor with a source and drain being connected to a first high voltage power supply (VDDQ) and an output terminal, respectively, a gate of the PMOS transistor being controlled by a first signal having a voltage swing between the VDDQ and a low voltage power supply (VSS), and a NMOS transistor with a source and drain being connected to the VSS and the output terminal, a gate of the NMOS transistor being controlled by a second signal having a voltage swing between a second high voltage power supply (VDD) and the VSS, wherein the VDD is lower than the VDDQ, and the voltage swings between the VDDQ and the VSS by the first signal and between the VDD and the VSS by the second signal are always in the same direction.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a schematic diagram illustrating a conventional CMOS inverter.

FIG. 2 is a schematic diagram illustrating a high voltage tolerative CMOS inverter according one embodiment of the present invention.

FIG. 3 is a schematic diagram illustrating a word-line driver employing the high voltage tolerative CMOS inverter of FIG. 2.

FIG. 4 is a schematic diagram illustrating a fuse module employing the high voltage tolerative CMOS inverter of FIG. 2.

The present invention is illustrated by way of example, and not by way of limitation, in the figures of the accompanying drawings in which like reference numerals refer to similar elements.

### DESCRIPTION

The following will provide a detailed description of a CMOS inverter structure that has improved high voltage tolerance.

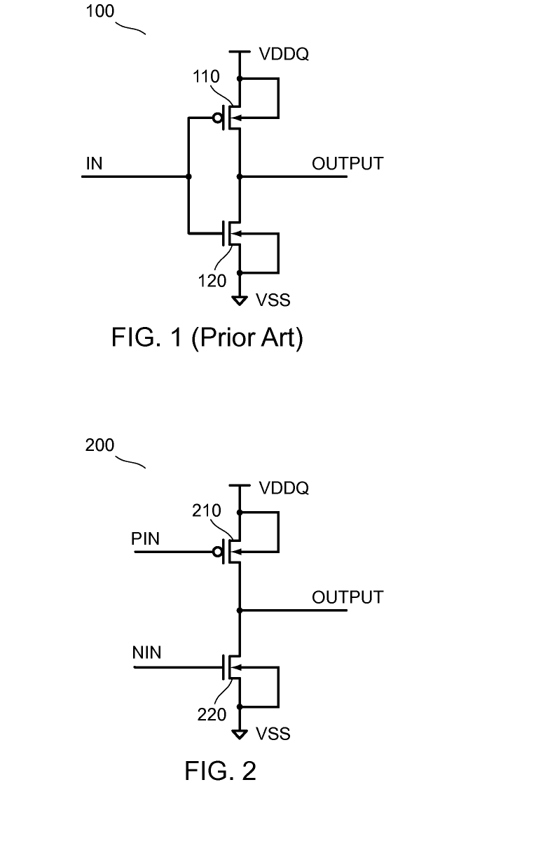

FIG. 2 is a schematic diagram illustrating a high voltage tolerative CMOS inverter 200 according to one embodiment of the present invention. Like the conventional CMOS inverter 100 shown in FIG. 1, the CMOS inverter 200 also has the PMOS transistor 210 and the NMOS transistor 220 serially connected between the VDDQ and the VSS with the drains commonly connected to the output terminal OUTPUT. However, the gates of the PMOS transistor 210 and the NMOS transistor 220 of FIG. 2 are not connected together to the single input terminal IN as shown in FIG. 1, instead they are separated with the gate of the PMOS transistor 210 connected to a first input terminal PIN, and the gate of the NMOS transistor 220 connected to a second input terminal NIN. The first input terminal PIN swings between the VDDQ and VSS, but the second input terminal NIN swings between another high voltage supply VDD, which is lower than the VDDQ, and the VSS. When a high voltage output at terminal OUTPUT is desired, both the input terminals, PIN and NIN will be supplied with the VSS. Then the PMOS transistor 210 will be turned on to pull the output terminal OUTPUT up to the VDDQ, and the NMOS transistor 220 will be turned off. When a low voltage output is desired at the output terminal OUTPUT, the input terminal of the PMOS transistor will be applied with the VDDQ which turns off the POMS transistor, and the gate of the NMOS transistor 220 will be supplied with the VDD which turns on the NMOS transistor 220, which in turn pull the output terminal OUTPUT to the VSS. In this way, the gate of the NMOS transistor 220 is never subjected to the VDDQ, which is the higher voltage that can cause damage to the gate oxide thereof. Even though the gate of the PMOS transistor 210 is still subjected to the VDDQ when the PIN is at the VSS, the PMOS gate oxide is much more robust than the NMOS gate oxide, referring to the Table 1, therefore, the overall high voltage tolerance of the inverter 200 is improved.

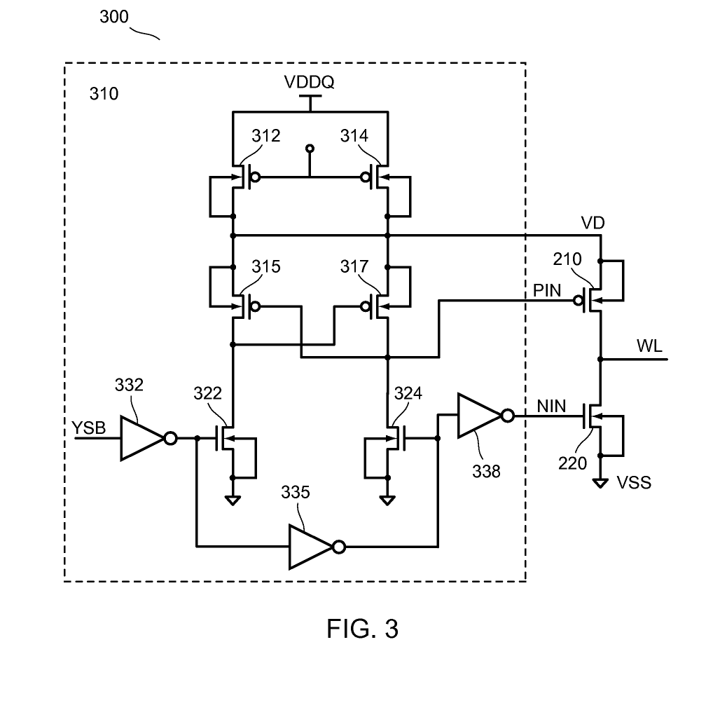

FIG. 3 is a schematic diagram illustrating a word-line driver 300 employing the high voltage tolerative CMOS inverter of FIG. 2. The word-line driver 300 includes a voltage-down converter 310 to provide the different voltages at the terminal PIN and NIN. PMOS transistors 312, 314, 315 and 317 can operate at the high voltage VDDQ. The cascoded PMOS transistors 312 and 315 drop the voltage for a NMOS transistor 322. Similarly the cascoded PMOS transistors 314 and 317 drop the voltage for a NMOS transistor 324. The NMOS transistors 322 and 324 as well as inverters 332 and 338 are operated at a relatively lower voltage supply, VDD (not shown). Therefore, the voltages are the nodes PIN and NIN are synchronized, i.e., when PIN is high, NIN is high, too, and vice versa, but PIN is significantly higher than NIN when both are at higher voltage. The circuit 310 is only an exemplary voltage down converter, a skilled artisan would have no difficulty to construct such circuit of different structure.

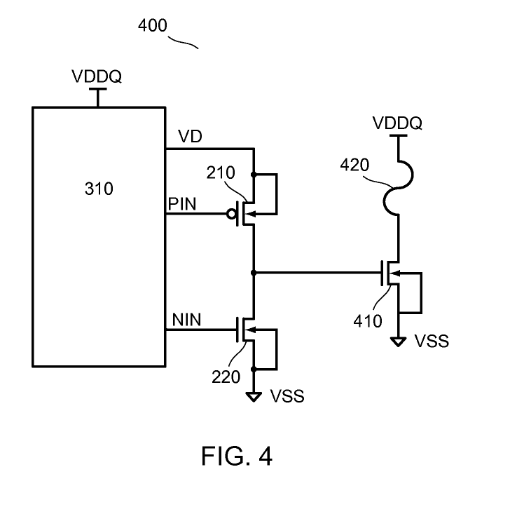

FIG. 4 is a schematic diagram illustrating a fuse module 400 employing the high voltage tolerative CMOS inverter of FIG. 2. The high voltage tolerative CMOS inverter outputs to the gate of a switching NMOS transistor 410. When the NMOS transistor 410 is turned on, a fuse 420 that is serially connected to the NMOS transistor 410 will be programmed. In a conventional CMOS inverter, during a power-on period, the PMOS transistor may be turned on for a very short period of time before the NMOS transistor is turned on. When the fuse module 400 is controlled by such conventional driver, the NMOS transistor 410 may be temporarily turned on during the power-on period, which may cause mis-programming of the fuse 420. However, when using the high voltage tolerative CMOS inverter with separated control gate voltage controls, the NMOS transistor 220 can be turned on earlier due to a less voltage rise which prevents the inverter from generating a voltage spike. Therefore, the fuse module 400 will not suffer mis-programming issue.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. A high voltage tolerative inverter circuit comprising:
a PMOS transistor with a source and drain being connected to a first high voltage power supply (VDDQ) and an output terminal, respectively, a gate of the PMOS transistor being controlled by a first signal having a voltage swing between the VDDQ and a low voltage power supply (VSS); and
a NMOS transistor with a source and drain being connected to the VSS and the output terminal, a gate of the NMOS transistor being controlled by a second signal having a voltage swing between a second high voltage power supply (VDD) and the VSS,
wherein the VDD is lower than the VDDQ, and the voltage swings between the VDDQ and the VSS by the first signal and between the VDD and the VSS by the second signal are always in the same direction.

2. The high voltage tolerative inverter circuit of claim 1, wherein the voltage swings by the first and second signals are simultaneous.

3. The high voltage tolerative inverter circuit of claim 1 further comprising a voltage down converter supplying both the first and second signals.

4. The high voltage tolerative inverter circuit of claim 2, wherein the voltage down converter comprises at least two cascoded PMOS transistors.

5. The high voltage tolerative inverter circuit of claim 1 further comprising an electrical fuse element in serial connection with a switching device, the switching device being controlled by the output of the high voltage tolerative inverter circuit.

6. The high voltage tolerative inverter circuit of claim 5, wherein the switching device is a NMOS transistor with a gate coupled to the output terminal of the high voltage tolerative inverter circuit.

7. A fuse control circuit comprising:
a PMOS transistor with a source and drain being connected to a first high voltage power supply (VDDQ) and an output terminal, respectively, a gate of the PMOS transistor being controlled by a first signal having a voltage swing between the VDDQ and a low voltage power supply (VSS);
a NMOS transistor with a source and drain being connected to the VSS and the output terminal, a gate of the NMOS transistor being controlled by a second signal having a voltage swing between a second high voltage power supply (VDD) and the VSS; and
an electrical fuse element in serial connection with a switching device, a control terminal of the switching device being coupled to the output terminal,
wherein the VDD is lower than the VDDQ, and the voltage swings between the VDDQ and the VSS by the first signal and between the VDD and the VSS by the second signal are always in the same direction.

8. The fuse control circuit of claim 7, wherein the voltage swings by the first and second signals are simultaneous.

9. The fuse control circuit of claim 7 further comprising a voltage down converter supplying both the first and second signals.

10. The fuse control circuit of claim 9, wherein the voltage down converter comprises at least two cascoded PMOS transistors.

11. The fuse control circuit of claim 7, wherein the switching device is a NMOS transistor with a gate coupled to the output terminal.

12. A high voltage tolerative inverter circuit comprising:
a PMOS transistor with a source and drain being connected to a first high voltage power supply (VDDQ) and an output terminal, respectively, a gate of the PMOS transistor being controlled by a first signal having a voltage swing between the VDDQ and a low voltage power supply (VSS);
a NMOS transistor with a source and drain being connected to the VSS and the output terminal, a gate of the NMOS transistor being controlled by a second signal having a voltage swing between a second high voltage power supply (VDD) and the VSS; and
a voltage down converter supplying both the first and second signals,
wherein the VDD is lower than the VDDQ, and the voltage swings between the VDDQ and the VSS by the first signal and between the VDD and the VSS by the second signal are always in the same direction.

13. The high voltage tolerative inverter circuit of claim 12, wherein the voltage swings by the first and second signals are simultaneous.

14. The high voltage tolerative inverter circuit of claim 12, wherein the voltage down converter comprises at least two cascoded PMOS transistors.

15. The high voltage tolerative inverter circuit of claim 12 further comprising an electrical fuse element in serial connection with a switching device, the switching device being controlled by the output of the high voltage tolerative inverter circuit.

16. The high voltage tolerative inverter circuit of claim 15, wherein the switching device is a NMOS transistor with a gate coupled to the output terminal of the high voltage tolerative inverter circuit.
